(19) United States
(12) Patent Application Publication
(10) Pub. No.: US 2025/0220858 A1
(43) Pub. Date: Jul. 3, 2025

(54) FLOW RATE CONTROL METHOD AND COMPUTING NODE

(71) Applicant: xFusion Digital Technologies Co., Ltd., Zhengzhou (CN)

(72) Inventors: Hui JIA, Zhengzhou (CN); Yongfu SUN, Zhengzhou (CN); Junfeng DING, Zhengzhou (CN)

(21) Appl. No.: 19/084,241

(22) Filed: Mar. 19, 2025

Related U.S. Application Data
(63) Continuation of application No. PCT/CN2023/097951, filed on Jun. 2, 2023.

(30) Foreign Application Priority Data
Sep. 26, 2022 (CN) 202211175094.7

(51) Int. Cl. H05K 7/20; G06F 1/20

(52) U.S. Cl. CPC H05K 7/20381; G06F 1/206; H05K 7/20345; G06F 2200/201

(57) ABSTRACT

This application provides a flow rate control method and a computing node. The method is applied to a computing node, the computing node includes a housing, a to-be-cooled component, and a nozzle, and the to-be-cooled component and the nozzle are located in a closed cavity of the housing. The method includes: obtaining a node parameter of the computing node, where the node parameter includes at least one of the following: a processor parameter of a processor and pressure information of the closed cavity, and the to-be-cooled component includes the processor; and adjusting, based on the node parameter, a flow rate of a liquid cooling medium sprayed by the nozzle to the to-be-cooled component.

### CROSS-REFERENCE TO RELATED APPLICATIONS

This application is a continuation of International Application No. PCT/CN2023/097951, filed on Jun. 2, 2023, which claims priority to Chinese Patent Application No. 202211175094.7, filed with the China National Intellectual Property Administration on Sep. 26, 2022 and entitled “FLOW RATE CONTROL METHOD AND COMPUTING NODE”, both of which are hereby incorporated by reference in its entirety.

### TECHNICAL FIELD

This application relates to the field of computer technologies, and in particular, to a flow rate control method and a computing node.

### BACKGROUND

A two-phase heat dissipation technology is a refrigeration technology used for a data center.

Currently, a plurality of computing nodes may be disposed in the data center. For example, the computing node may be a server. Each computing node may include at least one electronic component. For example, the electronic component may be a central processing unit (CPU) in the computing node. The computing node may be of a sealed structure, and a cooling medium may be accommodated in the computing node, to cool an electronic component in the computing node by using the cooling medium. For example, the cooling medium may be fluorinated liquid.

Inside the computing node, a liquid cooling medium may be sprayed by using a nozzle, so that the electronic component can be immersed in the liquid cooling medium. The liquid cooling medium can absorb heat generated by the electronic component and undergo vaporization, to remove the heat generated by the electronic component. However, if a spray speed of the liquid cooling medium is improper, a liquid level in the computing node may be too high or too low, resulting in a poor refrigeration effect in the computing node.

### BRIEF DESCRIPTION OF DRAWINGS

To describe the technical solutions in embodiments of this application or a conventional technology more clearly, the following briefly describes the accompanying drawings required for describing the embodiments or the conventional technology. Clearly, the accompanying drawings in the following description show merely some embodiments of this application, and one of ordinary skilled in the art may still derive other drawings from these accompanying drawings without creative efforts.

FIG. 1 is a schematic diagram of an architecture of a flow rate control system according to an embodiment of the application;

FIG. 2 is a schematic diagram of a nozzle flow rate control method;

FIG. 3A is a schematic diagram of a flow rate control method according to an embodiment of the application;

FIG. 3B is a schematic diagram of another flow rate control method according to an embodiment of the application;

FIG. 4 is a schematic flowchart of a flow rate control method according to an embodiment of the application;

FIG. 5 is a schematic flowchart of a method for adjusting a flow rate of a nozzle based on a processor parameter according to an embodiment of the application;

FIG. 6 is a schematic flowchart of another method for adjusting a flow rate of a nozzle based on a processor parameter according to an embodiment of the application;

FIG. 7 is a schematic flowchart of a method for adjusting a flow rate of a nozzle based on pressure information of a closed cavity according to an embodiment of the application;

FIG. 8 is a schematic flowchart of another method for adjusting a flow rate of a nozzle based on pressure information of a closed cavity according to an embodiment of the application;

FIG. 9 is a schematic diagram of a structure of a flow rate control apparatus according to an embodiment of the application; and

FIG. 10 is a schematic diagram of a hardware structure of a flow rate control device according to an embodiment of the application.

### DESCRIPTION OF EMBODIMENTS

Example embodiments are described herein in detail, and the examples are shown in the accompanying drawings. When the following descriptions relate to the accompanying drawings, unless otherwise indicated, same numbers in different accompanying drawings represent same or similar elements. Implementations described in the following example embodiments do not represent all implementations consistent with this application. On the contrary, they are merely examples of apparatuses and methods that are consistent with some aspects of this application as detailed in the appended claims.

It should be noted that in this specification, the term “include”, “contain”, or any other variant is intended to cover non-exclusive inclusion, so that a process, a method, an article, or an apparatus that includes a series of elements is not necessarily limited to these elements, but further includes other elements that are not clearly listed or further includes elements that are inherent to the process, the method, the article, or the apparatus. In the absence of more restrictions, an element defined by the statement “including a . . . ” does not rule out another same element in a process, a method, an article, or an apparatus that includes the element.

Embodiments of this application provide a flow rate control method and a computing node. In the method, a flow rate of a nozzle can be adjusted based on a node parameter of a computing node, to adjust a liquid level height in the computing node, so that a refrigeration effect of the computing node is better.

According to a first aspect, an embodiment of this application provides a flow rate control method, applied to a computing node. The computing node includes a housing, a to-be-cooled component, and a nozzle, the to-be-cooled component and the nozzle are located in a closed cavity of the housing, and the method includes:
obtaining a node parameter of the computing node, where the node parameter includes at least one of the following: a processor parameter of a processor and pressure information of the closed cavity, and the to-be-cooled component includes the processor; and
adjusting, based on the node parameter, a flow rate of a liquid cooling medium sprayed by the nozzle to the to-be-cooled component.

In the foregoing technical solution, the flow rate of the liquid cooling medium sprayed by the nozzle to the to-be-cooled component may be adjusted based on the node parameter, so as to adjust a liquid level height in the computing node to achieve a better heat dissipation effect of the computing node.

In an embodiment, the adjusting, based on the node parameter, a flow rate of a liquid cooling medium sprayed by the nozzle to the to-be-cooled component includes:
controlling, based on the processor parameter, the flow rate of the nozzle to increase or remain unchanged; or
controlling, based on the pressure information of the closed cavity, the flow rate of the nozzle to decrease or remain unchanged.

In the foregoing technical solution, the flow rate of the nozzle may be adjusted based on the processor parameter/the pressure information of the closed cavity, so that the flow rate of the nozzle is controlled with higher precision.

In an embodiment, the processor parameter includes a temperature of the processor, and the controlling, based on the processor parameter, the flow rate of the nozzle to increase or remain unchanged includes:
if the temperature of the processor is greater than or equal to a first preset temperature, controlling the flow rate of the nozzle to increase; or
if the temperature of the processor is less than the first preset temperature, controlling the flow rate of the nozzle to remain unchanged.

In the foregoing technical solution, the flow rate of the nozzle may be controlled to increase or remain unchanged based on whether the temperature of the processor exceeds the first preset temperature, so that control precision of the liquid level height of the cooling medium in the computing node is higher.

In an embodiment, the processor parameter includes a temperature of the processor, a temperature increase rate of the processor, and a first power increase rate of the processor.

The controlling, based on the processor parameter, the flow rate of the nozzle to increase or remain unchanged includes:
when the temperature increase rate is less than or equal to a first threshold, controlling the flow rate of the nozzle to remain unchanged; or
when the temperature increase rate is greater than the first threshold, controlling, based on the first power increase rate and the temperature of the processor, the flow rate of the nozzle to increase or remain unchanged.

In the foregoing technical solution, the flow rate of the nozzle may be adjusted based on the temperature increase rate of the processor, so that the flow rate of the nozzle is controlled with higher precision.

In an embodiment, the controlling, based on the first power increase rate and the temperature of the processor, the flow rate of the nozzle to increase or remain unchanged includes:
when the first power increase rate is less than or equal to a second threshold, controlling the flow rate of the nozzle to increase; or
when the first power increase rate is greater than the second threshold, if the temperature of the processor is greater than or equal to a second preset temperature, controlling the flow rate of the nozzle to increase; or if the temperature of the processor is less than the second preset temperature, controlling the flow rate of the nozzle to remain unchanged.

In the foregoing technical solution, the flow rate of the liquid cooling medium sprayed by the nozzle to the to-be-cooled component may be adjusted based on the temperature of the processor, the temperature increase rate of the processor, and the first power increase rate, so that control precision of the liquid level height of the cooling medium in the node is higher, and a heat dissipation effect of the computing node is better.

In an embodiment, the pressure information of the closed cavity includes a pressure in the closed cavity, and the controlling, based on the pressure information of the closed cavity, the flow rate of the nozzle to decrease or remain unchanged includes:
if the pressure in the closed cavity is greater than or equal to a first preset pressure, controlling the flow rate of the nozzle to decrease; or
if the pressure in the closed cavity is less than the first preset pressure, controlling the flow rate of the nozzle to remain unchanged.

In the foregoing technical solution, the flow rate of the nozzle may be controlled to decrease or remain unchanged based on whether the pressure in the closed cavity is greater than or equal to the first preset pressure, so that control precision of the liquid level height of the cooling medium in the node is higher, and a heat dissipation effect of the computing node is better.

In an embodiment, the pressure information of the closed cavity includes a pressure in the closed cavity and a pressure increase rate of the closed cavity. The controlling, based on the pressure information of the closed cavity, the flow rate of the nozzle to decrease or remain unchanged includes:
when the pressure increase rate is less than or equal to a third threshold, controlling the flow rate of the nozzle to remain unchanged; or
when the pressure increase rate is greater than the third threshold, controlling, based on a second power increase rate of the computing node and the pressure in the closed cavity, the flow rate of the nozzle to decrease or remain unchanged.

In the foregoing technical solution, the flow rate of the nozzle may be adjusted based on the pressure increase rate of the closed cavity, so that the flow rate of the nozzle is controlled with higher precision.

In an embodiment, the controlling, based on a second power increase rate and the pressure in the closed cavity, the flow rate of the nozzle to increase or remain unchanged includes:
when the second power increase rate is less than or equal to a fourth threshold, controlling the flow rate of the nozzle to decrease; or
when the second power increase rate is greater than the fourth threshold, if the pressure in the closed cavity is greater than or equal to a second preset pressure, controlling the flow rate of the nozzle to decrease; or if the pressure in the closed cavity is less than the second preset pressure, controlling the flow rate of the nozzle to remain unchanged.

In the foregoing technical solution, the flow rate of the liquid cooling medium sprayed by the nozzle to the to-be-cooled component may be adjusted based on the pressure increase rate of the closed cavity, the pressure in the closed cavity, and the second power increase rate, so that control precision of the liquid level height of the cooling medium in the node is higher, and a heat dissipation effect of the computing node is better.

According to a second aspect, an embodiment of this application provides a computing node, including a housing, a to-be-cooled component, a nozzle, and a controller. The to-be-cooled component and the nozzle are located in a closed cavity of the housing.

The controller is configured to execute the method in any one of the implementations of the first aspect, to adjust a flow rate of a liquid cooling medium sprayed by the nozzle to the to-be-cooled component.

In the foregoing technical solution, the flow rate of the nozzle may be adjusted by using the controller, so as to adjust a liquid level height in the closed cavity.

In an embodiment, the computing node further includes a pressure sensor, the pressure sensor is disposed in the closed cavity, and the pressure sensor is configured to collect a pressure in the closed cavity, and send the pressure in the closed cavity to the controller.

In the foregoing technical solution, the pressure sensor may be used to measure the pressure in the closed cavity, so as to implement monitoring of the pressure in the closed cavity.

According to a third aspect, an embodiment of this application provides a flow rate control apparatus. The flow rate control apparatus may be applied to a computing node, the computing node includes a housing, a to-be-cooled component, and a nozzle, and the to-be-cooled component and the nozzle are located in a closed cavity of the housing. The flow rate control apparatus includes an obtaining module and an adjustment module.

The obtaining module is configured to obtain a node parameter of the computing node. The node parameter includes at least one of the following: a processor parameter of a processor and pressure information of the closed cavity, and the to-be-cooled component includes the processor.

The adjustment module is configured to adjust, based on the node parameter, a flow rate of a liquid cooling medium sprayed by the nozzle to the to-be-cooled component.

In the foregoing technical solution, the flow rate of the liquid cooling medium sprayed by the nozzle to the to-be-cooled component may be adjusted based on the node parameter, so as to adjust a liquid level height in the computing node to achieve a better heat dissipation effect of the computing node.

In an embodiment, the adjustment module is configured to:
control, based on the processor parameter, the flow rate of the nozzle to increase or remain unchanged; or
control, based on the pressure information of the closed cavity, the flow rate of the nozzle to decrease or remain unchanged.

In the foregoing technical solution, the flow rate of the nozzle may be adjusted based on the processor parameter/the pressure information of the closed cavity, so that the flow rate of the nozzle is controlled with higher precision.

In an embodiment, the processor parameter includes a temperature of the processor. The adjustment module is configured to:
if the temperature of the processor is greater than or equal to a first preset temperature, control the flow rate of the nozzle to increase; or
if the temperature of the processor is less than the first preset temperature, control the flow rate of the nozzle to remain unchanged.

In the foregoing technical solution, the flow rate of the nozzle may be controlled to increase or remain unchanged based on whether the temperature of the processor exceeds the first preset temperature, so that control precision of the liquid level height of the cooling medium in the computing node is higher.

In an embodiment, the processor parameter includes a temperature of the processor, a temperature increase rate of the processor, and a first power increase rate of the processor. The adjustment module is configured to:
when the temperature increase rate is less than or equal to a first threshold, control the flow rate of the nozzle to remain unchanged; or
when the temperature increase rate is greater than the first threshold, control, based on the first power increase rate and the temperature of the processor, the flow rate of the nozzle to increase or remain unchanged.

In the foregoing technical solution, the flow rate of the nozzle may be adjusted based on the temperature increase rate of the processor, so that the flow rate of the nozzle is controlled with higher precision.

In an embodiment, the adjustment module is configured to:
when the first power increase rate is less than or equal to a second threshold, control the flow rate of the nozzle to increase; or
when the first power increase rate is greater than the second threshold, if the temperature of the processor is greater than or equal to a second preset temperature, control the flow rate of the nozzle to increase; or if the temperature of the processor is less than the second preset temperature, control the flow rate of the nozzle to remain unchanged.

In the foregoing technical solution, the flow rate of the liquid cooling medium sprayed by the nozzle to the to-be-cooled component may be adjusted based on the temperature of the processor, the temperature increase rate of the processor, and the first power increase rate, so that control precision of the liquid level height of the cooling medium in the node is higher, and a heat dissipation effect of the computing node is better.

In an embodiment, the pressure information includes a pressure in the closed cavity, and the adjustment module is configured to:
if the pressure in the closed cavity is greater than or equal to a first preset pressure, control the flow rate of the nozzle to decrease; or
if the pressure in the closed cavity is less than the first preset pressure, control the flow rate of the nozzle to remain unchanged.

In the foregoing technical solution, the flow rate of the nozzle may be controlled to decrease or remain unchanged based on whether the pressure in the closed cavity is greater than or equal to the first preset pressure, so that control precision of the liquid level height of the cooling medium in the node is higher, and a heat dissipation effect of the computing node is better.

In an embodiment, the pressure information includes a pressure in the closed cavity and a pressure increase rate of the closed cavity, and the adjustment module is configured to:
when the pressure increase rate is less than or equal to a third threshold, control the flow rate of the nozzle to remain unchanged; or
when the pressure increase rate is greater than the third threshold, control, based on a second power increase rate of the computing node and the pressure in the closed cavity, the flow rate of the nozzle to decrease or remain unchanged.

In the foregoing technical solution, the flow rate of the nozzle may be adjusted based on the pressure increase rate of the closed cavity, so that the flow rate of the nozzle is controlled with higher precision.

In an embodiment, the adjustment module is configured to:
when the second power increase rate is less than or equal to a fourth threshold, control the flow rate of the nozzle to decrease; or
when the second power increase rate is greater than the fourth threshold, if the pressure in the closed cavity is greater than or equal to a second preset pressure, control the flow rate of the nozzle to decrease; or if the pressure in the closed cavity is less than the second preset pressure, control the flow rate of the nozzle to remain unchanged.

In the foregoing technical solution, the flow rate of the liquid cooling medium sprayed by the nozzle to the to-be-cooled component may be adjusted based on the pressure increase rate of the closed cavity, the pressure in the closed cavity, and the second power increase rate, so that control precision of the liquid level height of the cooling medium in the node is higher, and a heat dissipation effect of the computing node is better.

According to a fourth aspect, an embodiment of this application provides a flow rate control device, including a processor and a memory that is communicatively connected to the processor.

The memory stores a computer program.

The processor executes the computer program to implement the method according to any one of the implementations of the first aspect.

In the foregoing technical solution, the flow rate of the liquid cooling medium sprayed by the nozzle to the to-be-cooled component may be adjusted based on the node parameter, so as to adjust a liquid level height in the computing node to achieve a better heat dissipation effect of the computing node.

According to a fifth aspect, an embodiment of this application provides a computer-readable storage medium. The computer-readable storage medium stores a computer program, and when the computer program is executed by a computer, the method according to any one of the implementations of the first aspect is implemented.

In the foregoing technical solution, the flow rate of the liquid cooling medium sprayed by the nozzle to the to-be-cooled component may be adjusted based on the node parameter, so as to adjust a liquid level height in the computing node to achieve a better heat dissipation effect of the computing node.

According to a sixth aspect, an embodiment of this application provides a computer program product, including a computer program. When the computer program is executed by a computer, the method according to any one of the implementations of the first aspect is implemented.

In the foregoing technical solution, the flow rate of the liquid cooling medium sprayed by the nozzle to the to-be-cooled component may be adjusted based on the node parameter, so as to adjust a liquid level height in the computing node to achieve a better heat dissipation effect of the computing node.

This application relates to a two-phase heat dissipation technology. To facilitate understanding of embodiments of this application, the two-phase heat dissipation technology is first described in detail.

Two-phase heat dissipation is a refrigeration technology in which a liquid cooling medium absorbs heat generated by an electronic component and undergoes vaporization, to remove the heat generated by the electronic component, and the gaseous cooling medium is condensed into a liquid cooling medium by another device, to continue to cool the electronic component.

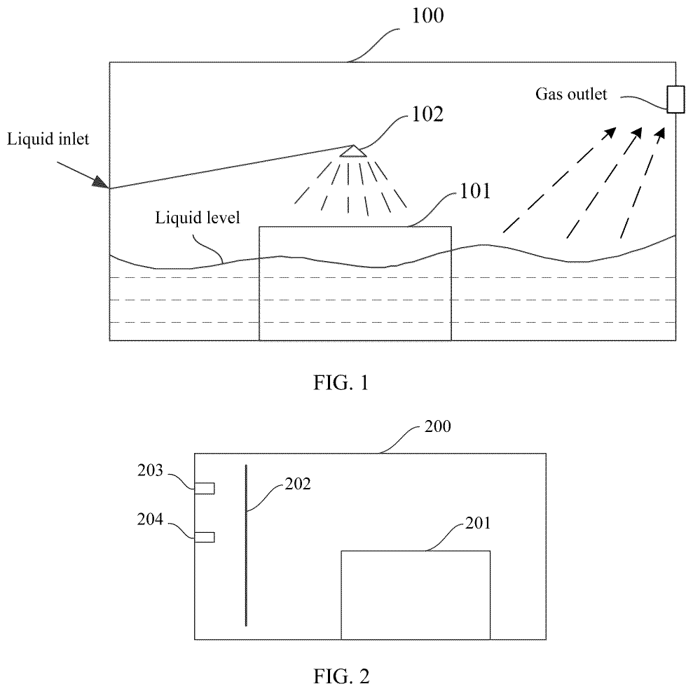

For ease of understanding, the following describes an architecture of a flow rate control system in embodiments of this application with reference to FIG. 1.

FIG. 1 is a schematic diagram of an architecture of a flow rate control system according to an embodiment of this application. As shown in FIG. 1, a computing node 100 is included. The computing node 100 includes a to-be-cooled component 101 and a nozzle 102.

The computing node 100 may be a server, a server cluster, or the like that is disposed in a data center. One or more electronic components may be disposed in the computing node 100. Heat is generated when the electronic component works.

The to-be-cooled component 101 may be a heating component in the computing node 100. For example, the to-be-cooled component 101 may be a central processing unit (CPU), a graphics processing unit (GPU) circuit board, a memory, or the like.

The nozzle 102 is configured to spray a cooling medium to the to-be-cooled component 101, so that the to-be-cooled component 101 may be immersed in the cooling medium. It should be understood that there may be one or more nozzles 102. This is not limited in an embodiment of the application.

In the foregoing flow rate control system, the computing node 100 has a closed cavity, and the closed cavity may be configured to accommodate the to-be-cooled component 101, the nozzle 102, the cooling medium, and the like. A liquid inlet and a gas outlet are disposed on walls of the cavity of the computing node 100. The liquid inlet is configured to allow a liquid cooling medium to enter the computing node 100, and the liquid inlet is connected to the nozzle 102. The nozzle 102 may spray a liquid cooling medium to the processor. The liquid cooling medium may absorb heat generated by the to-be-cooled component 101, and undergo vaporization. The vaporized cooling medium may be exported from the gas outlet of the computing node 100.

It should be noted that the system architecture and the application scenario described in an embodiment of the application are intended to describe the technical solutions in embodiments of this application more clearly, and do not constitute a limitation on the technical solutions provided in embodiments of this application. The structure of the computing node shown in an embodiment of the application does not constitute a limitation on the computing node. The computing node may include more or fewer components than those shown in the figure, or combine some components, or split some components, or have different component arrangements. The components shown in the figure may be implemented by hardware, software, or a combination of software and hardware.

In the foregoing flow rate control system, a flow rate of the nozzle 102 may be controlled, so that a liquid level in the computing node 100 is maintained at a proper height, thereby implementing cooling of the computing node 100. For example, the liquid level may be lower than the height of the to-be-cooled component 101 in a vertical direction, or the liquid level may be higher than the height of the to-be-cooled component 101 in the vertical direction. In embodiments of this application, the height of the liquid level is not limited provided that the height of the liquid level can meet a heat dissipation requirement of the computing node 100.

With reference to FIG. 2, the following shows a nozzle flow rate control method by using an example.

FIG. 2 is a schematic diagram of a method for controlling nozzle flow rate. As shown in FIG. 2, a computing node 200 includes a processor 201, a baffle 202, a liquid level sensor 203, and a liquid level sensor 204.

The liquid level sensor 203 and the liquid level sensor 204 are disposed on a side wall that is of the computing node 200 and that is close to the baffle 202. The liquid level sensor 203 and the liquid level sensor 204 may be configured to detect a liquid level height in the computing node 200, so that the computing node 200 can adjust a flow rate of a nozzle based on the liquid level height. For example, if the liquid level height is higher than a position at which the liquid level sensor 203 is disposed, the computing node 200 controls the flow rate of the nozzle to decrease; if the liquid level height is lower than a position at which the liquid level sensor 204 is disposed, the computing node 200 controls the flow rate of the nozzle to increase.

However, the liquid level in the computing node 200 fluctuates easily, and when the liquid level fluctuates frequently, it is difficult for the liquid level sensor 203 and/or the liquid level sensor 204 to determine a height of the liquid level in the computing node 200. Consequently, the computing node 200 cannot accurately control the flow rate of the nozzle, and a cooling effect in the computing node is poor.

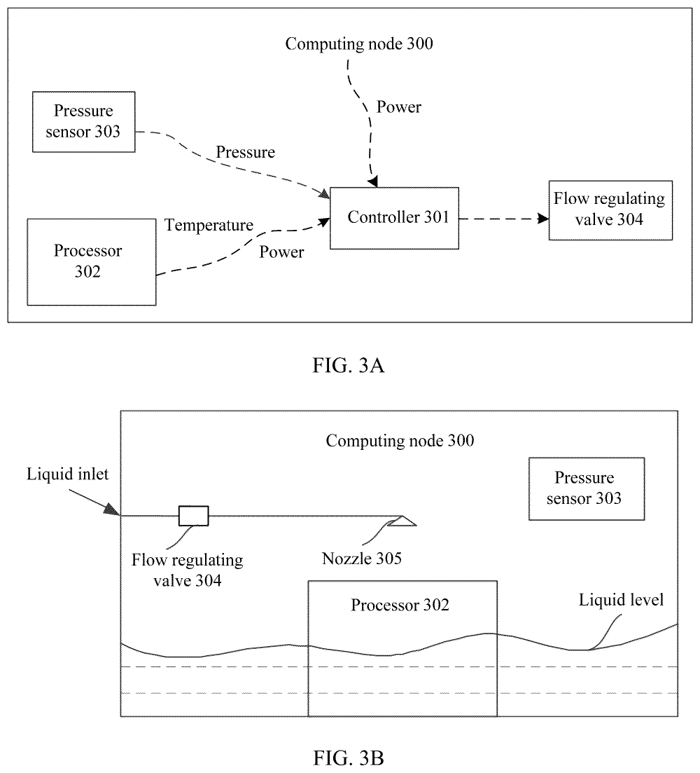

In view of this, embodiments of this application provide a flow rate control method. With reference to FIG. 3A and FIG. 3B, the following describes the flow rate control method provided in embodiments of this application.

FIG. 3A is a schematic diagram of a flow rate control method according to an embodiment of this application. As shown in FIG. 3A, a computing node 300 includes a controller 301, a processor 302, a pressure sensor 303, and a flow regulating valve 304.

The processor 302 may be a to-be-cooled component with high heat generation in the computing node.

The controller 301 may be a management module of a non-business module in the computing node 300. For example, the controller 301 may be a baseboard management controller (BMC) outside the computing node 300, a monitoring and management device outside the computing node 300, a management system in a management chip excluding the processor, a system management module (SMM) of the computing node 300, or the like. A form of the controller 301 is not limited in an embodiment of the application, and the foregoing is merely an example description. In the following embodiment, an example in which the controller 301 is a BMC is used for description.

The controller 301 may monitor a temperature of the processor 302, power of the processor 302, and power of the computing node 300. The pressure sensor 303 may measure a pressure in a closed cavity of the computing node 300. The controller 301 may be connected (communicatively) to the pressure sensor 303, to monitor the pressure in the closed cavity of the computing node 300 by using the pressure sensor 303. The controller 301 may further adjust an opening degree of the flow regulating valve 304 based on the temperature of the processor 302, the power of the processor 302, the power of the computing node 300, and the pressure in the closed cavity.

FIG. 3B is a schematic diagram of another flow rate control method according to an embodiment of this application. As shown in FIG. 3B, on the basis of FIG. 3A, the computing node 300 may further include a nozzle 305.

The flow regulating valve 304 may be connected to the nozzle 305 and may be configured to adjust a spray flow rate of the nozzle 305. The processor 302 may be immersed in a cooling medium sprayed by the nozzle 305. The pressure sensor 303 is disposed above a liquid level, so that fluctuation of the liquid level does not affect a measurement result of the pressure sensor 303. For example, the pressure sensor 303 may be disposed at an upper cover position of the closed cavity in the computing node 300.

According to the method shown in FIG. 3A and FIG. 3B, the controller 301 may adjust the opening degree of the flow regulating valve 304 based on the temperature of the processor 302, the power of the processor 302, the power of the computing node 300, and the pressure in the closed cavity, so as to adjust the spray flow rate of the nozzle 305, to adjust a height of the liquid level in the computing node 300, thereby improving a refrigeration effect of the computing node 300.

The following describes the technical solutions of this application in detail by using embodiments. The following several embodiments may be combined with each other. A same or similar concept or process may not be described again in some embodiments.

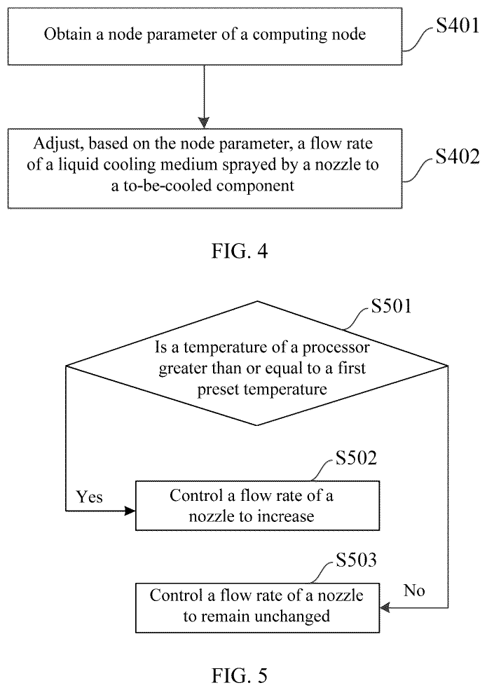

FIG. 4 is a schematic flowchart of a flow rate control method according to an embodiment of this application. As shown in FIG. 4, the method may include the following operations.

S401: Obtain a node parameter of a computing node.

An embodiment may be executed by a controller or a flow rate control device in the controller. In an embodiment, the flow rate control device may be implemented by using software, or may be implemented by combining software and hardware.

The computing node includes a housing, a to-be-cooled component, and a nozzle, and the to-be-cooled component and the nozzle are located in a closed cavity of the housing.

The computing node may be an electronic device that generates heat during working. For example, the computing node may be a server.

The to-be-cooled component may be a heating component in the computing node. For example, the to-be-cooled component may be a circuit board, a CPU, a GPU, a memory, or the like in the computing node.

The nozzle may be configured to spray a cooling medium to the to-be-cooled component, to implement cooling of the to-be-cooled component. For example, the cooling medium may be fluorinated liquid.

The node parameter includes at least one of the following: a processor parameter of a processor and pressure information of the closed cavity. The to-be-cooled component includes the processor.

The processor may be a component that generates a large amount of heat in the computing node. For example, the processor may be a CPU.

The processor parameter may be status data in a running process of the processor. For example, the processor parameter may be a temperature of the processor, or the like.

The pressure information of the closed cavity may be a pressure in the closed cavity that is configured to accommodate the to-be-cooled component and the nozzle.

In an embodiment, the controller may directly or indirectly obtain the node parameter. For example, the controller may directly monitor and obtain running status data of the node; or the controller may obtain the node parameter from another monitoring device. For example, the another monitoring device may be a temperature sensor, a pressure sensor, or the like.

S402: Based on the node parameter, adjust a flow rate of a liquid cooling medium sprayed by the nozzle to the to-be-cooled component.

It should be understood that the flow rate of the nozzle and/or a liquid level height in the closed cavity may affect a heat dissipation effect of the computing node. For example, if the flow rate of the nozzle is small, a liquid level may be too low, resulting in a poor heat dissipation effect; if the liquid level is too high, the closed cavity may be filled with the cooling medium, resulting in a poor heat dissipation effect.

In an embodiment, the flow rate of the nozzle may be controlled to increase or remain unchanged based on the processor parameter. Alternatively, the flow rate of the nozzle is controlled to decrease or remain unchanged based on the pressure information of the closed cavity.

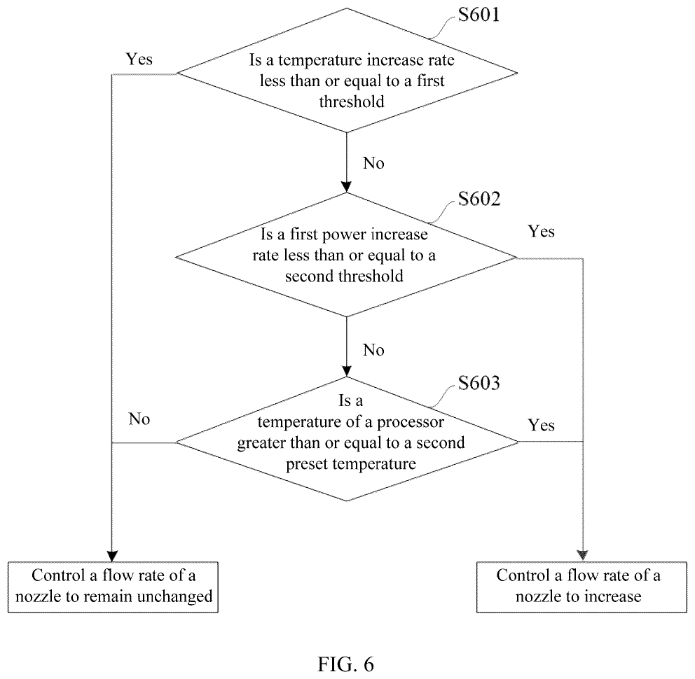

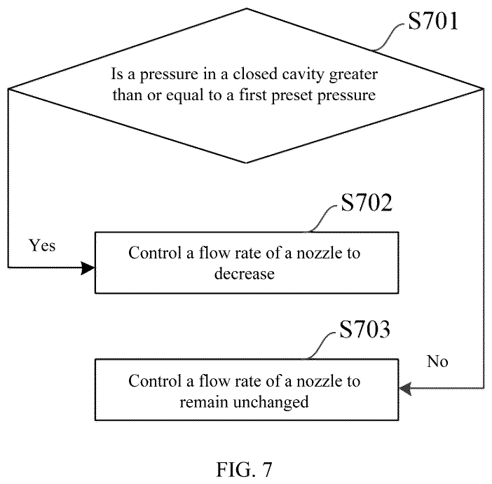

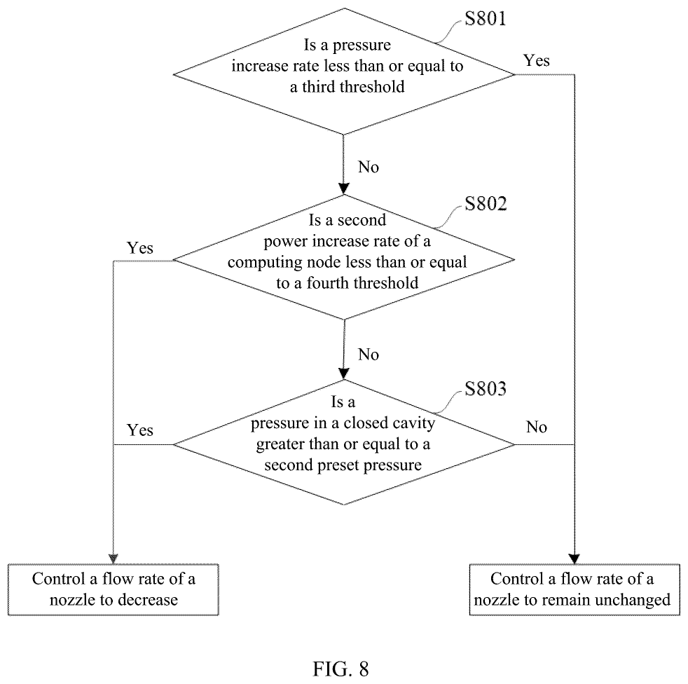

It should be noted that a method for controlling, based on a processor parameter, a flow rate of a nozzle to increase or remain unchanged is described in detail in embodiments shown in FIG. 5 and FIG. 6, and a method for controlling, based on pressure information of a closed cavity, a flow rate of a nozzle to decrease or remain unchanged is described in detail in embodiments shown in FIG. 7 and FIG. 8. Details are not described herein again.

In the flow rate control method provided in an embodiment, the node parameter of the computing node may be obtained, and the flow rate of the liquid cooling medium sprayed by the nozzle to the to-be-cooled component is adjusted based on the node parameter, so as to adjust the liquid level height in the computing node to achieve a better heat dissipation effect of the computing node.

On the basis of the embodiment in FIG. 4, different processor parameters lead to different methods for controlling the flow rate of the nozzle to increase or remain unchanged, which may include the following two cases:

Case 1: The processor parameter includes a temperature of the processor.

The temperature of the processor may be a current working temperature of the processor.

It should be understood that the controller may monitor and obtain the working temperature of the processor.

Case 2: The processor parameter includes a temperature of the processor, a temperature increase rate of the processor, and a first power increase rate of the processor.

The temperature increase rate of the processor may be a temperature increase rate of the processor in a first time period between a moment before a current moment and the current moment. A length of the first time period may be set based on an actual requirement. This is not limited in this application.

It should be understood that the controller may obtain the temperature increase rate of the processor through calculation based on working temperatures of the processor.

The first power increase rate may be a power increase rate of the processor in a second time period between a moment before the current moment and the current moment. The second time period may be the same as the first time period, or the second time period may be different from the first time period. A length of the second time period may be set based on an actual requirement. This is not limited in this application.

It should be understood that the controller may monitor power of the processor, and may obtain the first power increase rate through calculation based on the power of the processor.

With reference to FIG. 5 and FIG. 6, the following describes the method for controlling, based on the processor parameter, the flow rate of the nozzle to increase or remain unchanged in the foregoing two cases.

The following describes the foregoing case 1 with reference to FIG. 5. FIG. 5 is a schematic flowchart of a method for adjusting the flow rate of the nozzle based on the processor parameter according to an embodiment of this application. As shown in FIG. 5, the method may include the following operations.

S501: Determine whether the temperature of the processor is greater than or equal to a first preset temperature.

If yes, S502 is executed.

If no, S503 is executed.

The first preset temperature may be a warning temperature of the processor. The warning temperature may be lower than a maximum working temperature of the processor.

Warning temperatures of a plurality of levels may be set based on an actual requirement. For example, a temperature lower than the maximum temperature of the processor by 10° C. may be set to a critical warning temperature, and a temperature lower than the maximum temperature of the processor by 15° C. may be set to a general warning temperature.

For example, if the maximum working temperature of the processor is 100° C., the warning temperatures of the processor may be shown in Table 1:

TABLE 1

| Warning temperatures | Warning levels |
|---|---|
| 95° C. | Emergency warning |
| 90° C. | Critical warning |
| 85° C. | General warning |

It should be noted that the first preset temperature in an embodiment may be set to a warning temperature of any one of the foregoing levels based on an actual heat dissipation requirement.

S502: Control the flow rate of the nozzle to increase.

If the temperature of the processor is greater than or equal to the first preset temperature, a current flow rate of the nozzle may not meet a heat dissipation requirement of the processor, and therefore the flow rate of the nozzle needs to be controlled to increase.

S503: Control the flow rate of the nozzle to remain unchanged.

If the temperature of the processor is less than the first preset temperature, that is, the current temperature of the processor meets a working requirement, a current speed of spraying the cooling medium by the nozzle may be controlled to remain unchanged.

In the method for adjusting the flow rate of the nozzle based on the processor parameter provided in an embodiment, the flow rate of the nozzle may be controlled to increase or remain unchanged based on whether the temperature of the processor exceeds the first preset temperature, so that control precision of the liquid level height of the cooling medium in the computing node is higher, and a heat dissipation effect of the computing node is better.

The following describes the foregoing case 2 with reference to FIG. 6. FIG. 6 is a schematic flowchart of another method for adjusting the flow rate of the nozzle based on the processor parameter according to an embodiment of this application. As shown in FIG. 6, the method may include the following operations.

S601: Determine whether the temperature increase rate is less than or equal to a first threshold.

If yes, the flow rate of the nozzle is controlled to remain unchanged.

If no, S602 is executed.

The first threshold may be an alarm value that is of the temperature increase rate of the processor and that is set based on a heat dissipation requirement of the computing node.

It should be noted that when the temperature increase rate of the processor is greater than the first threshold, there is a possibility that a current heat dissipation policy does not meet the heat dissipation requirement of the computing node, that is, the flow rate of the nozzle may need to be adjusted. For example, the first threshold may be 3° C./min. The heat dissipation policy may be the flow rate of the cooling medium sprayed by the nozzle.

S602: Determine whether the first power increase rate is less than or equal to a second threshold.

If yes, the flow rate of the nozzle is controlled to increase.

If no, S603 is executed.

The second threshold may be an alarm value that is of the power increase rate of the processor and that is set based on a heat dissipation requirement of the computing node.

On the basis of S601, if the first power increase rate is less than or equal to the second threshold, the current heat dissipation policy does not meet the heat dissipation requirement of the computing node, and the flow rate of the nozzle needs to be controlled to increase; or if the first power increase rate is greater than the second threshold, there is a possibility that the current heat dissipation policy does not meet a refrigeration requirement of the computing node, and the computing node may need to adjust the flow rate of the nozzle. For example, the second threshold may be 10 W/min.

It should be noted that if the temperature increase rate is greater than the first threshold, and the first power increase rate is less than or equal to the second threshold, the temperature of the processor may be increased due to an insufficient liquid level height in the closed cavity, and therefore the flow rate of the nozzle needs to be controlled to increase.

For example, it is assumed that the first threshold is 3° C./min and the second threshold is 10 W/min. In this case, when the temperature increase rate is greater than 3° C./min and the first power increase rate is less than or equal to 10 W/min, the flow rate of the nozzle needs to be controlled to increase.

S603: Determine whether the temperature of the processor is greater than or equal to a second preset temperature.

If yes, the flow rate of the nozzle is controlled to increase.

If no, the flow rate of the nozzle is controlled to remain unchanged.

The second preset temperature may be a warning temperature of the processor. The second preset temperature may be the same as the first preset temperature, or the second preset temperature may be different from the first preset temperature.

On the basis of S601 and S602, if the temperature of the processor is greater than or equal to the second preset temperature, the current heat dissipation policy does not meet the heat dissipation requirement of the computing node, and the flow rate of the nozzle needs to be increased.

It should be noted that if the temperature increase rate is greater than the first threshold, the first power increase rate is greater than the second threshold, and the temperature of the processor is greater than or equal to the second preset temperature, the current flow rate of the nozzle is too small to meet the heat dissipation requirement of the processor, and therefore the flow rate of the nozzle needs to be controlled to increase.

For example, it is assumed that the first threshold is 3° C./min, the second threshold is 10 W/min, and the second preset temperature is 90° C. In this case, when the temperature increase rate is greater than 3° C./min, the first power increase rate is greater than 10 W/min, and the temperature of the processor is greater than or equal to 90° C., the flow rate of the nozzle needs to be controlled to increase.

In the method for adjusting the flow rate of the nozzle based on the processor parameter provided in an embodiment, the flow rate of the liquid cooling medium sprayed by the nozzle to the to-be-cooled component can be adjusted based on the temperature of the processor, the temperature increase rate of the processor, and the first power increase rate, so that control precision of the liquid level height of the cooling medium in the node is higher, and a heat dissipation effect of the computing node is better.

On the basis of any one of the foregoing embodiments, a method for controlling the flow rate of the nozzle to decrease or remain unchanged varies with pressure information of the closed cavity. The method may include the following two cases:

Case 1: The pressure information of the closed cavity includes the pressure in the closed cavity.

The pressure in the closed cavity may be a current pressure in the closed cavity that is obtained by the controller through monitoring by using a pressure sensor in the closed cavity.

Case 2: The pressure information of the closed cavity includes the pressure in the closed cavity and a pressure increase rate of the closed cavity.

The pressure increase rate of the closed cavity may be a rate at which the pressure in the closed cavity increases in a third time period between a moment before a current moment and the current moment. The third time period may be the same as the first time period/the second time period, or the third time period may be different from the first time period/the second time period. A length of the third time period may be set based on an actual requirement. This is not limited in this application.

It should be understood that the controller may monitor pressures in the closed cavity, and may obtain the pressure increase rate of the closed cavity through calculation based on the pressures in the closed cavity.

With reference to FIG. 7 and FIG. 8, the following describes the method for controlling, based on the pressure information of the closed cavity, the flow rate of the nozzle to increase or remain unchanged in the foregoing two cases.

The following describes the foregoing case 1 with reference to FIG. 7. FIG. 7 is a schematic flowchart of a method for adjusting the flow rate of the nozzle based on the pressure information of the closed cavity according to an embodiment of this application. As shown in FIG. 7, the method may include the following operations.

S701: Determine whether the pressure in the closed cavity is greater than or equal to a first preset pressure.

If yes, S702 is executed.

If no, S703 is executed.

The first preset pressure may be a warning pressure of the closed cavity of the computing node. The warning pressure may be lower than a maximum working pressure in the closed cavity.

In an embodiment, warning pressures of a plurality of levels may be set based on an actual requirement. For example, a pressure that is lower than the maximum working pressure in the closed cavity by 4 kPa may be set to a critical warning pressure, and a pressure that is lower than the maximum working pressure in the closed cavity by 5 kPa may be set to a general warning pressure.

For example, if the maximum working pressure in the closed cavity is 15 kPa, the warning pressures of the closed cavity may be shown in Table 2:

TABLE 2

| Warning pressures | Warning levels |
|---|---|
| 12 kPa | Emergency warning |
| 11 kPa | Critical warning |
| 10 kPa | General warning |

It should be noted that the first preset pressure in an embodiment may be set to a warning pressure of any one of the foregoing levels based on a heat dissipation requirement of the computing node.

S702: Control the flow rate of the nozzle to decrease.

If the pressure in the closed cavity is greater than or equal to the first preset pressure, the current liquid level in the closed cavity may be too high, and the flow rate of the nozzle needs to be controlled to decrease.

S703: Control the flow rate of the nozzle to remain unchanged.

If the pressure in the closed cavity is less than the first preset pressure, the current liquid level height in the closed cavity may meet the heat dissipation requirement, and the flow rate of the nozzle may be controlled to remain unchanged.

In the method for adjusting the flow rate of the nozzle based on the pressure information of the closed cavity provided in an embodiment, the flow rate of the nozzle may be controlled to decrease or remain unchanged based on whether the pressure in the closed cavity is greater than or equal to the first preset pressure, so that control precision of the liquid level height of the cooling medium in the node is higher, and a heat dissipation effect of the computing node is better.

The following describes the foregoing case 2 with reference to FIG. 8. FIG. 8 is a schematic flowchart of another method for adjusting the flow rate of the nozzle based on the pressure information of the closed cavity according to an embodiment of this application. As shown in FIG. 8, the method may include the following operations.

S801: Determine whether the pressure increase rate is less than or equal to a third threshold.

If yes, the flow rate of the nozzle is controlled to remain unchanged.

If no, S802 is executed.

The third threshold may be an alarm value that is of the pressure increase rate in the closed cavity and that is set based on a heat dissipation requirement of the computing node.

It should be noted that when the pressure increase rate is greater than the third threshold, there is a possibility that a current heat dissipation policy does not meet the heat dissipation requirement of the computing node, that is, the flow rate of the nozzle may need to be adjusted. For example, the third threshold may be 3 kPa/min. The heat dissipation policy may be the flow rate of the cooling medium sprayed by the nozzle.

S802: Determine whether a second power increase rate of the computing node is less than or equal to a fourth threshold.

If yes, the flow rate of the nozzle is controlled to decrease.

If no, S803 is executed.

The second power increase rate may be a power increase rate of the computing node in a fourth time period between a moment before a current moment and the current moment. The fourth time period may be the same as the first time period/the second time period/the third time period, or the fourth time period may be different from the first time period/the second time period/the third time period. A length of the fourth time period may be set based on an actual requirement. This is not limited in this application.

It should be understood that the controller may monitor power of the computing node, and may calculate the second power increase rate based on the power of the computing node.

The fourth threshold may be an alarm value that is of the power increase rate of the computing node and that is set based on the heat dissipation requirement of the computing node.

On the basis of S801, if the second power increase rate is less than or equal to the fourth threshold, the current heat dissipation policy does not meet the heat dissipation requirement of the computing node, and the flow rate of the nozzle needs to be controlled to decrease. For example, the fourth threshold may be 100 W/min.

It should be noted that if the pressure increase rate is greater than the third threshold and the second power increase rate is less than or equal to the fourth threshold, the pressure in the closed cavity may be increased due to an excessively high liquid level in the closed cavity, and therefore the flow rate of the nozzle needs to be controlled to decrease.

For example, it is assumed that the third threshold is 3 kPa/min and the fourth threshold is 100 W/min. In this case, when the pressure increase rate is greater than 3 kPa/min and the second power increase rate is less than or equal to 100 W/min, the flow rate of the nozzle needs to be controlled to decrease.

S803: Determine whether the pressure in the closed cavity is greater than or equal to a second preset pressure.

If yes, the flow rate of the nozzle is controlled to decrease.

If no, the flow rate of the nozzle is controlled to remain unchanged.

The second preset pressure may be a warning pressure of the closed cavity. The second preset pressure may be the same as the first preset pressure, or the second preset pressure may be different from the first preset pressure.

On the basis of S801 and S802, if the pressure in the closed cavity is greater than or equal to the second preset pressure, the current heat dissipation policy does not meet the heat dissipation requirement of the computing node, and the flow rate of the nozzle needs to be controlled to decrease.

It should be noted that if the pressure increase rate is greater than the third threshold, the second power increase rate is greater than the fourth threshold, and the pressure in the closed cavity is greater than or equal to the second preset pressure, a boiling height of the liquid level in the closed cavity is relatively high, and therefore the flow rate of the nozzle needs to be controlled to decrease.

For example, it is assumed that the third threshold is 3 kPa/min, the fourth threshold is 100 W/min, and the second preset pressure is 10 kPa. In this case, when the pressure increase rate is greater than 3 kPa/min, the second power increase rate is greater than 100 W/min, and the pressure in the closed cavity is greater than or equal to 3 kPa/min, the flow rate of the nozzle needs to be controlled to decrease.

In the method for adjusting the flow rate of the nozzle based on the pressure information of the closed cavity provided in an embodiment, the flow rate of the liquid cooling medium sprayed by the nozzle to the to-be-cooled component may be adjusted based on the pressure increase rate of the closed cavity, the pressure in the closed cavity, and the second power increase rate, so that control precision of the liquid level height of the cooling medium in the node is higher, and a heat dissipation effect of the computing node is better.

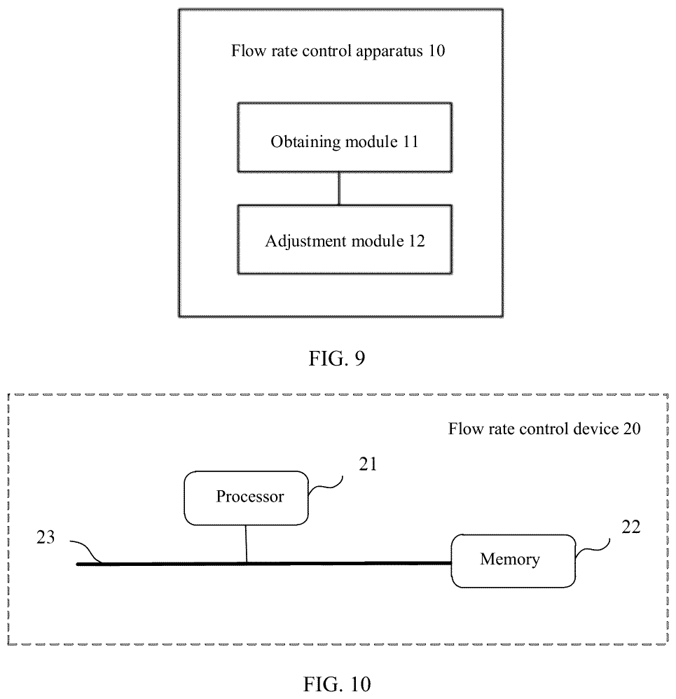

FIG. 9 is a schematic diagram of a structure of a flow rate control apparatus according to an embodiment of this application. As shown in FIG. 9, the flow rate control apparatus 10 may be applied to a computing node, and the computing node includes a housing, a to-be-cooled component, and a nozzle. The to-be-cooled component and the nozzle are located in a closed cavity of the housing. The flow rate control apparatus 10 includes an obtaining module 11 and an adjustment module 12.

The obtaining module 11 is configured to obtain a node parameter of the computing node. The node parameter includes at least one of the following: a processor parameter of a processor and pressure information of the closed cavity, and the to-be-cooled component includes the processor.

The adjustment module 12 is configured to adjust, based on the node parameter, a flow rate of a liquid cooling medium sprayed by the nozzle to the to-be-cooled component.

The flow rate control apparatus provided in an embodiment may be configured to execute the technical solutions shown in any one of the foregoing method embodiments. Implementation principles and technical effects of the apparatus are similar to those of the method, and details are not described herein again.

In an embodiment, the adjustment module 12 is configured to:
control, based on the processor parameter, the flow rate of the nozzle to increase or remain unchanged; or
control, based on the pressure information of the closed cavity, the flow rate of the nozzle to decrease or remain unchanged.

In an embodiment, the processor parameter includes a temperature of the processor, and the adjustment module 12 is configured to:
if the temperature of the processor is greater than or equal to a first preset temperature, control the flow rate of the nozzle to increase; or
if the temperature of the processor is less than the first preset temperature, control the flow rate of the nozzle to remain unchanged.

In an embodiment, the processor parameter includes a temperature of the processor, a temperature increase rate of the processor, and a first power increase rate of the processor. The adjustment module 12 is configured to:
when the temperature increase rate is less than or equal to a first threshold, control the flow rate of the nozzle to remain unchanged; or
when the temperature increase rate is greater than the first threshold, control, based on the first power increase rate and the temperature of the processor, the flow rate of the nozzle to increase or remain unchanged.

In an embodiment, the adjustment module 12 is configured to:
when the first power increase rate is less than or equal to a second threshold, control the flow rate of the nozzle to increase; or
when the first power increase rate is greater than the second threshold, if the temperature of the processor is greater than or equal to a second preset temperature, control the flow rate of the nozzle to increase; or if the temperature of the processor is less than the second preset temperature, control the flow rate of the nozzle to remain unchanged.

In an embodiment, the pressure information includes a pressure in the closed cavity, and the adjustment module 12 is configured to:
if the pressure in the closed cavity is greater than or equal to a first preset pressure, control the flow rate of the nozzle to decrease; or
if the pressure in the closed cavity is less than the first preset pressure, control the flow rate of the nozzle to remain unchanged.

In an embodiment, the pressure information includes a pressure in the closed cavity and a pressure increase rate of the closed cavity, and the adjustment module 12 is configured to:
when the pressure increase rate is less than or equal to a third threshold, control the flow rate of the nozzle to remain unchanged; or
when the pressure increase rate is greater than the third threshold, control, based on a second power increase rate of the computing node and the pressure in the closed cavity, the flow rate of the nozzle to decrease or remain unchanged.

In an embodiment, the adjustment module 12 is configured to:
when the second power increase rate is less than or equal to a fourth threshold, control the flow rate of the nozzle to decrease; or
when the second power increase rate is greater than the fourth threshold, if the pressure in the closed cavity is greater than or equal to a second preset pressure, control the flow rate of the nozzle to decrease; or if the pressure in the closed cavity is less than the second preset pressure, control the flow rate of the nozzle to remain unchanged.

The flow rate control apparatus provided in an embodiment may be configured to execute the technical solutions shown in any one of the foregoing method embodiments. Implementation principles and technical effects of the apparatus are similar to those of the method, and details are not described herein again.

FIG. 10 is a schematic diagram of a hardware structure of a flow rate control device according to an embodiment of the application. As shown in FIG. 10, the flow rate control device 20 may include a processor 21 and a memory 22. The processor 21 and the memory 22 may communicate with each other. For example, the processor 21 communicates with the memory 22 through a communication bus 23. The memory 22 is configured to store program instructions, and the processor 21 is configured to invoke the program instructions in the memory to execute the flow rate control method shown in any one of the foregoing method embodiments.

In an embodiment, the flow rate control device 20 may further include a communication interface, and the communication interface may include a transmitter and/or a receiver.

In an embodiment, the processor may be a central processing unit (CPU), or may be another general-purpose processor, a digital signal processor (DSP), an application integrated circuit (ASIC), or the like. The general-purpose processor may be a microprocessor, or the processor may be any conventional processor or the like. The operations of the methods disclosed in this application may be directly executed by a hardware processor, or executed by a combination of hardware and software modules in the processor.

An embodiment of this application further provides a computer-readable storage medium. The computer-readable storage medium stores a computer program. When the computer program is executed by a computer, the flow rate control method executed in any one of the foregoing method embodiments is implemented. Implementation principles and technical effects of the computer-readable storage medium are similar to those of the method, and details are not described herein again.

An embodiment of this application further provides a computer program product, including a computer program. When the computer program is executed by a computer, the flow rate control method executed in any one of the foregoing method embodiments is implemented. Implementation principles and technical effects of the computer program product are similar to those of the method, and details are not described herein again.

An embodiment of this application further provides a computing node, including a housing, a to-be-cooled component, a nozzle, and a controller. The to-be-cooled component and the nozzle are located in a closed cavity of the housing.

The controller is configured to execute the method in any one of the foregoing method embodiments, to adjust a flow rate of a liquid cooling medium sprayed by the nozzle to the to-be-cooled component.

In an embodiment, the computing node further includes a pressure sensor, the pressure sensor is disposed in the closed cavity, and the pressure sensor is configured to collect a pressure in the closed cavity, and send the pressure in the closed cavity to the controller.

The computing node provided in an embodiment may be configured to execute the technical solutions shown in any one of the foregoing method embodiments. Implementation principles and technical effects of the computing node are similar to those of the method, and details are not described herein again.

All or some of the operations of the foregoing method embodiments may be implemented by a program instructing related hardware. The foregoing program may be stored in a readable memory. When the program is being executed, the operations in the foregoing method embodiments are performed. The foregoing memory (storage medium) includes a read-only memory (ROM), a RAM, a flash memory, a hard disk, a solid state disk, a magnetic tape, a floppy disk, an optical disc, and any combination thereof.

Embodiments of this application are described with reference to a flowchart and/or a block diagram of a method, a device (system), and a computer program product according to the embodiments of this application. It should be understood that each process and/or block in the flowchart and/or block diagram and a combination of processes and/or blocks in the flowchart and/or block diagram may be implemented by computer program instructions. These computer program instructions may be provided for a processing unit of a general-purpose computer, a dedicated computer, an embedded processor, or another programmable terminal device to generate a machine, so that instructions executed by a processing unit of a computer or another programmable terminal device generate an apparatus for implementing a function specified in one or more processes in the flowchart and/or one or more blocks in the block diagram.

These computer program instructions may also be stored in a computer-readable memory that can instruct a computer or another programmable terminal device to work in a manner, so that instructions stored in the computer-readable memory generate an artifact including an instruction apparatus. The instruction apparatus implements a function specified in one or more processes in the flowchart and/or one or more blocks in the block diagram.

These computer program instructions may also be loaded onto a computer or another programmable terminal device, so that a series of operation steps are performed on the computer or the another programmable device to generate computer-implemented processing, and instructions executed on the computer or the another programmable device provide operations for implementing a function specified in one or more processes in the flowchart and/or one or more blocks in the block diagram.

Clearly, one of ordinary skilled in the art may make various modifications and variations to the embodiments of this application without departing from the spirit and scope of this application. In this way, if these modifications and variations in the embodiments of this application fall within the scope of the claims of this application and the equivalent technologies thereof, this application also intends to include these modifications and variations.

In this application, the term “including” and a variant thereof may refer to non-limiting inclusion, and the term “or” and a variant thereof may refer to “and/or”. In this application, terms “first”, “second”, and the like are used to distinguish between similar objects, and do not need to be used to describe a sequence or order. In this application, “a plurality of” refers to two or more, and “and/or” describes an association relationship between associated objects, and indicates that there may be three relationships, for example, A and/or B may indicate three cases: Only A exists, both A and B exist, and only B exists. The character “/” generally indicates an “or” relationship between associated objects.

What is claimed is:

1. A flow rate control method applied to a computing node, comprising:
obtaining a node parameter of the computing node, wherein the computing node comprises a housing, a cooled component, and a nozzle, the cooled component and the nozzle are located in a closed cavity of the housing, wherein the node parameter comprises at least one of: a processor parameter of a processor and pressure information of the closed cavity, or the cooled component comprises the processor; and
adjusting, based on the node parameter, a flow rate of a liquid cooling medium sprayed by the nozzle to the cooled component.

2. The method according to claim 1, wherein adjusting the flow rate of the liquid cooling medium sprayed by the nozzle to the cooled component comprises:
controlling, based on the processor parameter, the flow rate of the nozzle to increase or remain unchanged; or
controlling, based on the pressure information of the closed cavity, the flow rate of the nozzle to decrease or remain unchanged.

3. The method according to claim 2, wherein the processor parameter comprises a temperature of the processor, and controlling the flow rate of the nozzle to increase or remain unchanged comprises:
if the temperature of the processor is greater than or equal to a first preset temperature, controlling the flow rate of the nozzle to increase; or
if the temperature of the processor is less than the first preset temperature, controlling the flow rate of the nozzle to remain unchanged.

4. The method according to claim 2, wherein the processor parameter comprises a temperature of the processor, a temperature increase rate of the processor, and a first power increase rate of the processor; and
controlling the flow rate of the nozzle to increase or remain unchanged comprises:
in response to determining the temperature increase rate is less than or equal to a first threshold, controlling the flow rate of the nozzle to remain unchanged; or
in response to determining the temperature increase rate is greater than the first threshold, controlling, based on the first power increase rate and the temperature of the processor, the flow rate of the nozzle to increase or remain unchanged.

5. The method according to claim 4, wherein controlling the flow rate of the nozzle to increase or remain unchanged comprises:
in response to determining the first power increase rate is less than or equal to a second threshold, controlling the flow rate of the nozzle to increase; or
in response to determining the first power increase rate is greater than the second threshold, if the temperature of the processor is greater than or equal to a second preset temperature, controlling the flow rate of the nozzle to increase; or if the temperature of the processor is less than the second preset temperature, controlling the flow rate of the nozzle to remain unchanged.

6. The method according to claim 2, wherein the pressure information of the closed cavity comprises a pressure in the closed cavity, and controlling the flow rate of the nozzle to decrease or remain unchanged comprises:
if the pressure in the closed cavity is greater than or equal to a first preset pressure, controlling the flow rate of the nozzle to decrease; or
if the pressure in the closed cavity is less than the first preset pressure, controlling the flow rate of the nozzle to remain unchanged.

7. The method according to claim 2, wherein the pressure information of the closed cavity comprises a pressure in the closed cavity and a pressure increase rate of the closed cavity, and controlling the flow rate of the nozzle to decrease or remain unchanged comprises:
in response to determining the pressure increase rate is less than or equal to a third threshold, controlling the flow rate of the nozzle to remain unchanged; or
in response to determining the pressure increase rate is greater than the third threshold, controlling, based on a second power increase rate of the computing node and the pressure in the closed cavity, the flow rate of the nozzle to decrease or remain unchanged.

8. The method according to claim 7, wherein controlling the flow rate of the nozzle to increase or remain unchanged comprises:
in response to determining the second power increase rate is less than or equal to a fourth threshold, controlling the flow rate of the nozzle to decrease; or
in response to determining the second power increase rate is greater than the fourth threshold, if the pressure in the closed cavity is greater than or equal to a second preset pressure, controlling the flow rate of the nozzle to decrease; or if the pressure of the closed cavity is less than the second preset pressure, controlling the flow rate of the nozzle to remain unchanged.

9. A computing node, comprising:
a housing,
a cooled component,
a nozzle, wherein the cooled component and the nozzle are located in a closed cavity of the housing, and
a controller configured to perform:
obtaining a node parameter of the computing node, wherein the node parameter comprises at least one of: a processor parameter of a processor and pressure information of the closed cavity, or the cooled component comprises the processor; and
adjusting a flow rate of a liquid cooling medium sprayed by the nozzle to the cooled component.

10. The computing node according to claim 9, further comprising:
a pressure sensor disposed in the closed cavity, wherein the pressure sensor is configured to collect a pressure in the closed cavity, and send the pressure in the closed cavity to the controller.

11. The computing node according to claim 9, wherein adjusting the flow rate of the liquid cooling medium sprayed by the nozzle to the cooled component comprises:
controlling, based on the processor parameter, the flow rate of the nozzle to increase or remain unchanged; or
controlling, based on the pressure information of the closed cavity, the flow rate of the nozzle to decrease or remain unchanged.

12. The computing node according to claim 11, wherein the processor parameter comprises a temperature of the processor, and controlling the flow rate of the nozzle to increase or remain unchanged comprises:
if the temperature of the processor is greater than or equal to a first preset temperature, controlling the flow rate of the nozzle to increase; or
if the temperature of the processor is less than the first preset temperature, controlling the flow rate of the nozzle to remain unchanged.

13. The computing node according to claim 11, wherein the processor parameter comprises a temperature of the processor, a temperature increase rate of the processor, and a first power increase rate of the processor; and
controlling the flow rate of the nozzle to increase or remain unchanged comprises:
in response to determining the temperature increase rate is less than or equal to a first threshold, controlling the flow rate of the nozzle to remain unchanged; or
in response to determining the temperature increase rate is greater than the first threshold, controlling, based on the first power increase rate and the temperature of the processor, the flow rate of the nozzle to increase or remain unchanged.

14. The computing node according to claim 13, wherein controlling the flow rate of the nozzle to increase or remain unchanged comprises:
in response to determining the first power increase rate is less than or equal to a second threshold, controlling the flow rate of the nozzle to increase; or
in response to determining the first power increase rate is greater than the second threshold, if the temperature of the processor is greater than or equal to a second preset temperature, controlling the flow rate of the nozzle to increase; or if the temperature of the processor is less than the second preset temperature, controlling the flow rate of the nozzle to remain unchanged.

15. The computing node according to claim 11, wherein the pressure information of the closed cavity comprises a pressure in the closed cavity, and controlling the flow rate of the nozzle to decrease or remain unchanged comprises:
if the pressure in the closed cavity is greater than or equal to a first preset pressure, controlling the flow rate of the nozzle to decrease; or
if the pressure in the closed cavity is less than the first preset pressure, controlling the flow rate of the nozzle to remain unchanged.

16. The computing node according to claim 11, wherein the pressure information of the closed cavity comprises a pressure in the closed cavity and a pressure increase rate of the closed cavity, and controlling the flow rate of the nozzle to decrease or remain unchanged comprises:
in response to determining the pressure increase rate is less than or equal to a third threshold, controlling the flow rate of the nozzle to remain unchanged; or
in response to determining the pressure increase rate is greater than the third threshold, controlling, based on a second power increase rate of the computing node and the pressure in the closed cavity, the flow rate of the nozzle to decrease or remain unchanged.

17. The computing node according to claim 16, wherein controlling the flow rate of the nozzle to increase or remain unchanged comprises:
in response to determining the second power increase rate is less than or equal to a fourth threshold, controlling the flow rate of the nozzle to decrease; or
in response to determining the second power increase rate is greater than the fourth threshold, if the pressure in the closed cavity is greater than or equal to a second preset pressure, controlling the flow rate of the nozzle to decrease; or if the pressure of the closed cavity is less than the second preset pressure, controlling the flow rate of the nozzle to remain unchanged.
